(19) United States
(12) Patent Application Publication
(10) Pub. No.: US 2025/0365862 A1
(43) Pub. Date: Nov. 27, 2025

(54) INTEGRATED RESISTANCE-BASED SENSING COMPONENTS ON AN ALUMINUM FLEX CIRCUIT

(71) Applicant: Manaflex, LLC, Waikoloa, HI (US)

(72) Inventors: Robert C. LANE, Las Vegas, NV (US); Yifei LIU, Toronto (CA)

(21) Appl. No.: 19/213,190

(22) Filed: May 20, 2025

Related U.S. Application Data
(60) Provisional application No. 63/650,986, filed on May 23, 2024.

(51) Int. Cl. H05K 1/03; G01R 27/02; H05K 1/02; H05K 1/18

(52) U.S. Cl. CPC H05K 1/0393; H05K 1/028; H05K 1/0298; H05K 1/181; G01R 27/02; H05K 2201/10151

(57) ABSTRACT

Resistance-based sensors, such as thermistors and photoresistors, can be placed on and/or be integrated directly to an aluminum-based flex circuit. The process of coupling a resistance-based sensor does not require an additional circuit or adaptor circuit for the sensors. The sensor can be mechanically bonded directly to the sensing target directly from the flex circuit. Some exemplary bonding methods include, but are not limited to, welding or adhesion.

### CROSS-REFERENCE TO RELATED APPLICATION

This application is a non-provisional application of, and claims priority to and the benefit of, U.S. Provisional Patent App. No. 63/650,986, entitled “INTEGRATED RESISTANCE-BASED SENSING COMPONENTS ON AN ALUMINUM FLEX CIRCUIT”, filed May 23, 2024, with Attorney Docket No. 4375.0018P, the entire disclosure of which is incorporated by reference herein in its entirety.

### FIELD OF INVENTION

The present invention relates to flex circuits, and in particular to integrated resistance-based sensing components on an aluminum flex circuit.

### BACKGROUND

Flex circuits have shortcomings that need to be addressed.

### SUMMARY OF THE INVENTION

In one aspect of the present disclosure, an aluminum-based flex circuit comprises a first coverlayer, the first coverlayer including an opening formed therein, a second coverlayer, an aluminum layer positioned between the first coverlayer and the second coverlayer, and a resistance-based sensor located in the opening in the first coverlayer.

In one embodiment, the opening in the first coverlayer is a first opening, and the first coverlayer includes a second opening formed therein spaced apart from the first opening.

In another embodiment, the second coverlayer includes a third opening formed therein, and the third opening in the second coverlayer is aligned with the second opening in the first coverlayer.

In an alternative embodiment, the resistance-based sensor is a first resistance-based sensor, and the aluminum-based flex circuit further comprises a second resistance-based sensor located in the second opening in the first coverlayer and in the third opening in the second coverlayer.

In yet another embodiment, the second resistance-based sensor is bonded to an external component proximate to the aluminum-based flex circuit.

In one embodiment, aluminum-based flex circuit further comprises an adhesive material located between the second coverlayer and an external component proximate to the aluminum-based flex circuit.

In another embodiment, the aluminum layer is a first aluminum layer, and the aluminum-based flex circuit further comprises a third coverlayer, and a second aluminum layer located between the second coverlayer and the third coverlayer, wherein the third coverlayer is proximate to an external component.

In an alternative embodiment, the second aluminum layer is thicker than the first aluminum layer.

### BRIEF DESCRIPTION OF THE DRAWINGS

To complete the description and in order to provide for a better understanding of the present application, a set of drawings is provided. The drawings form an integral part of the description and illustrate embodiments of the present application, which should not be interpreted as restricting the scope of the invention, but just as examples. The drawings comprise the following figures.

FIG. 1 illustrates a schematic drawing of an embodiment of an aluminum flex circuit according to an aspect of this disclosure.

FIG. 2 illustrates a schematic drawing of another embodiment of an aluminum flex circuit according to an aspect of this disclosure.

FIG. 3 illustrates a schematic drawing of another embodiment of an aluminum flex circuit according to an aspect of this disclosure.

FIG. 4 illustrates a schematic drawing of another embodiment of an aluminum flex circuit according to an aspect of this disclosure.

Like reference numerals have been used to identify like elements throughout this disclosure.

### DETAILED DESCRIPTION

The following description is not to be taken in a limiting sense but is given solely for the purpose of describing the broad principles of the invention. Embodiments of the invention will be described by way of example, with reference to the above-mentioned drawings showing elements and results according to the present invention.

Resistance-based sensors, such as thermistors and photoresistors, can be placed on and/or be integrated directly to an aluminum-based flex circuit. The process of coupling a resistance-based sensor does not require an additional circuit or adaptor circuit for the sensors.

In one embodiment, the sensor can be mechanically bonded directly to the sensing target directly from the flex circuit. Some exemplary bonding methods include, but are not limited to, welding or adhesion.

In one embodiment, the aluminum circuit can be nickel-plated, either fully plated or partially plated, to allow sensors to be soldered to the circuit.

An advantage of the present invention is that it simplifies the assembly and process.

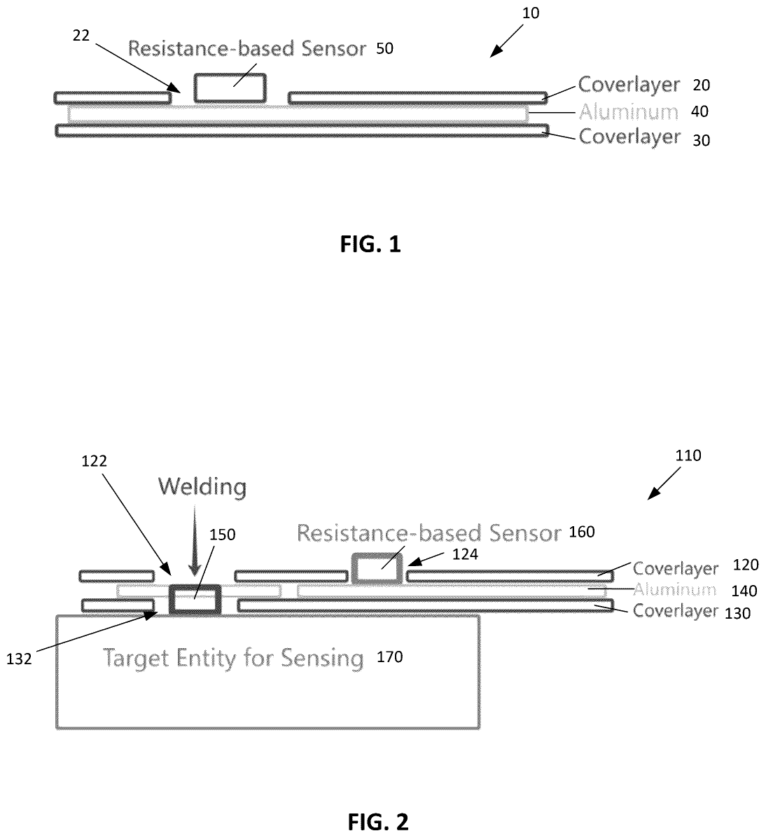

Turning to FIG. 1, a schematic drawing of an embodiment of an aluminum flex circuit according to an aspect of this disclosure is illustrated. In FIG. 1, a cross-sectional view at a circuit-level of an aluminum-based flex circuit 10 is shown. In this embodiment, the aluminum-based flex circuit 10 includes a pair of coverlayers 20 and 30 between which a layer of aluminum material 40 is located. Coverlayer 20 includes a gap or opening 22 in which a resistance-based sensor 50 is located.

Turning to FIG. 2, a schematic drawing of another embodiment of an aluminum flex circuit according to an aspect of this disclosure is illustrated. In FIG. 2, a cross-sectional assembly level illustration of an aluminum-based flex circuit 110 is shown. In this embodiment, a resistance-based sensor is bonded to a target 170 through welding. The aluminum-based flex circuit 110 includes a pair of coverlayers 120 and 130 between which a layer of aluminum material 140 is located. Coverlayer 120 has gaps or openings 122 formed therein. Coverlayer 130 has a gap or opening 132 formed therein. A resistance-based sensor 150 is located in the gaps 122 and 132 in coverlayers 120 and 130, respectively, and is bonding via welding to a target entity for sensing 170. The aluminum-based flex circuit 110 also includes a resistance-based sensor 160 that is located in gap or opening 124 in coverlayer 120.

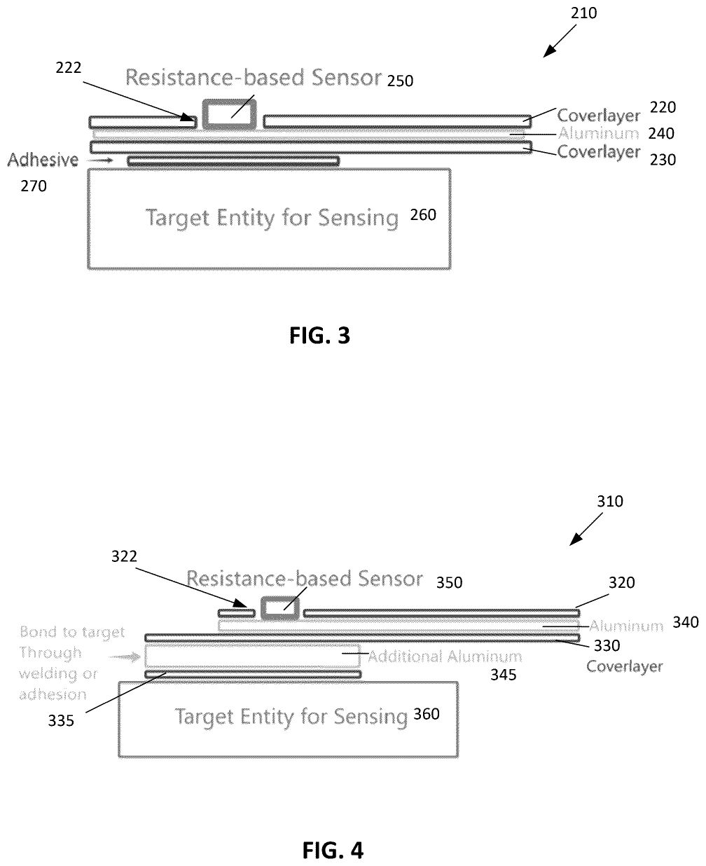

Turning to FIG. 3, a schematic drawing of another embodiment of an aluminum flex circuit according to an aspect of this disclosure is illustrated. In FIG. 3, a cross-sectional assembly level illustration of an aluminum-based flex circuit 210 is shown. In this embodiment, a resistance-based sensor is bonded to a target through adhesion. The aluminum-based flex circuit 210 includes a pair of coverlayers 220 and 230 between which a layer of aluminum material 240 is located. Coverlayer 220 has a gap or opening 222 formed therein in which resistance-based sensor 250 is located. An adhesive 270 is used to bond to a target entity for sensing 260.

Turning to FIG. 4, a schematic drawing of another embodiment of an aluminum flex circuit according to an aspect of this disclosure is illustrated. In FIG. 4, a cross-sectional assembly level illustration of an aluminum-based flex circuit 310 is shown. In this embodiment, the aluminum-based flex circuit 310 is a multi-layer circuit. The aluminum-based flex circuit 310 includes a pair of coverlayers 320 and 330 between which a layer of aluminum material 340 is located. The aluminum-based flex circuit 310 also includes an additional coverlayer 335 and an additional layer of aluminum material 345 located between coverlayer 330 and coverlayer 335. The aluminum layer 345 is bonded to a target entity for sensing 360 through either welding or adhesion.

It should be noted that in this document, the terms “comprising”, “including”, or any other variants thereof, are intended to encompass non-exclusive inclusion, so that processes, methods, articles, or devices comprising a series of elements include not only those elements explicitly listed, but also other elements not explicitly listed, or even elements inherent to such processes, methods, articles, or devices. In the absence of further limitations, the elements limited by the phrase “including one . . . ” do not exclude other identical elements in processes, methods, articles, or devices including the specified elements.

What is claimed is:

1. An aluminum-based flex circuit, comprising:
a first coverlayer, the first coverlayer including an opening formed therein;
a second coverlayer;
an aluminum layer positioned between the first coverlayer and the second coverlayer; and
a resistance-based sensor located in the opening in the first coverlayer.

2. The aluminum-based flex circuit of claim 1, wherein the opening in the first coverlayer is a first opening, and the first coverlayer includes a second opening formed therein spaced apart from the first opening.

3. The aluminum-based flex circuit of claim 1, wherein the second coverlayer includes a third opening formed therein, and the third opening in the second coverlayer is aligned with the second opening in the first coverlayer.

4. The aluminum-based flex circuit of claim 3, wherein the resistance-based sensor is a first resistance-based sensor, and the aluminum-based flex circuit further comprises:
a second resistance-based sensor located in the second opening in the first coverlayer and in the third opening in the second coverlayer.

5. The aluminum-based flex circuit of claim 4, wherein the second resistance-based sensor is bonded to an external component proximate to the aluminum-based flex circuit.

6. The aluminum-based flex circuit of claim 1, further comprising:
an adhesive material located between the second coverlayer and an external component proximate to the aluminum-based flex circuit.

7. The aluminum-based flex circuit of claim 1, wherein the aluminum layer is a first aluminum layer, the aluminum-based flex circuit further comprising:
a third coverlayer; and
a second aluminum layer located between the second coverlayer and the third coverlayer, wherein the third coverlayer is proximate to an external component.

8. The aluminum-based flex circuit of claim 7, wherein the second aluminum layer is thicker than the first aluminum layer.
